(19) United States
(12) Patent Application Publication
(10) Pub. No.: US 2010/0062550 A1
(43) Pub. Date: Mar. 11, 2010

(54) METHOD FOR REDUCING OCCURRENCE OF SHORT-CIRCUIT FAILURE IN AN ORGANIC FUNCTIONAL DEVICE

(75) Inventors: Michael Buchel, Eindhoven (NL); Edward Willem Albert Young, Eindhoven (NL); Adrianus Sempel, Eindhoven (NL); Ivar Jacco Boerefijn, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/993,317

(22) PCT Filed: Jun. 27, 2006
(86) PCT No.: PCT/IB06/52106

§ 371 Date: Dec. 20, 2007

(30) Foreign Application Priority Data
Jun. 30, 2005 (EP) 05105864.2

(51) Int. Cl. H01L 21/66; G01R 31/26

(52) U.S. Cl. 438/17; 324/765; 257/E21.531

(57) ABSTRACT

A method, for reducing occurrence of short-circuit failure in an organic functional device (101, 201, 401) comprising a first transparent electrode layer (104), a second electrode layer (105) and an organic functional layer (103) sandwiched between said first and second electrode layers (104; 105). The method comprises the steps of identifying (301) a portion of said organic functional device (101, 201, 401), said portion containing a defect (102a-g) leading to an increased risk of short-circuit failure, selecting (302) a segment (108a-g) of said second electrode layer (105), said segment corresponding to said portion, and electrically isolating (303) said segment (108a-g) from a remainder of said second electrode layer (105), thereby eliminating short-circuit failure resulting from said defect (102a-g).

The present invention relates to a method for reducing occurrence of short-circuit failure in an organic functional device comprising a first transparent electrode layer, a second electrode layer and an organic functional layer sandwiched between said first and second electrode layers.

Common for all organic functional devices, such as organic light emitting diodes (OLEDs), organic solar cells, organic photovoltaic elements, organic photo diodes, organic photosensors etc., is that at least one organic layer is sandwiched between and interacts with a pair of electrode layers. In an OLED, the application of a voltage between the electrode layers results in emission of light by the organic layer and in an organic solar cell, absorption of light by the organic layer leads to the creation of a voltage between the electrode layers.

When manufacturing organic functional devices, defects occur with a certain probability. Some defects may be of minor importance only and the device can in such a case be delivered to a customer without any dissatisfaction on the customer's side. Other defects may render the device useless to the customer and such a device may consequently not be shipped. Of particular importance are defects which are not visible at the time of manufacture, but which lead to errors, typically short-circuit failure, occuring while the device is in use. Apart from leading to customer dissatisfaction, such errors can, when occuring during the warranty time, lead to substantial direct costs for the manufacturing company. Generally, devices with an increased probability of short-circuit failure during operation can be identified and disposed of before shipping. In some cases, however, such a procedure may lead to an unacceptably low production yield.

In this context, the Japanese patent application JP2004199970 should be mentioned. In this document, a method for detecting and repairing short-circuits in an electroluminiscence (EL) display is disclosed. According to this method, a short-circuit location is detected with high precision using two microscopes—one optical microscope and one infrared microscope. Following this detection, the short circuit location is irradiated and “burned away” by a laser.

A problem with the approach of JP2004199970 is that a very high precision is needed to exactly locate and remove short-circuits. Normally, high precision requires costly equipment and/or long time. Furthermore, the method according to JP2004199970 appears only to be suitable for short-circuits resulting from point-defects.

There is thus a need for an improved and more cost-efficient method for reducing occurrence of short-circuit failures.

In view of the above-mentioned and other drawbacks of the prior art, a general object of the present invention is to provide an improved method for reducing occurrence of short-circuit failures in an organic functional device.

A further object of the present invention is to enable a more cost-efficient reduction of the occurrence of such short-circuit failures.

According to the invention, these and other objects are achieved through a method, for reducing occurrence of short-circuit failure in an organic functional device comprising a first transparent electrode layer, a second electrode layer and an organic functional layer sandwiched between the first and second electrode layers, comprising the steps of identifying a portion of the organic functional device, this portion containing a defect leading to an increased risk of short-circuit failure, selecting a segment of the second electrode layers, the segment corresponding to the portion, and electrically isolating the segment from a remainder of the second electrode layer, thereby eliminating short-circuit failure resulting from the defect.

Examples of organic functional devices include organic light-emitting diodes (OLEDs), organic photocells, organic photovoltaic elements, organic photodiodes and organic photosensors.

By the term “electrode layer” should be understood an electrically conductive layer which could be transparent or non-transparent to light.

The transparent electrode layer may, for example, be manufactured of any material, which is inherently conductive and transparent or, alternatively, of a sufficiently thin metal layer, which could be provided in combination with a transparent conductive or non-conductive layer.

The organic functional layer may consist of many different organic layers with different functions (such as hole injection, hole transport, hole blocking, excitation blocking, electron blocking, electron transport, electron injection or light emitting, light absorbing layers), or mixtures thereof, but may also include metal-organic materials like triplet emitters or inorganic materials such as dielectric, semi-conducting or metallic quantum dots or nano-particles.

The identified defect could be an already developed short-circuit or it could be a defect, which may lead to the occurrence of a short-circuit failure at a later stage. Such a defect may, for instance, be a speck of dust or other foreign material trapped inside the device during manufacturing or a pin-hole or the like.

Such a defect may occur in any one of the layers comprised in the device or between layers. Typically, a defect is identified as a two-dimensional portion of the device.

Through the method according to the invention, defects, which may develop into short-circuits, as well as actual short-circuit-defects can be taken care of. The occurrence of short-circuit failure during operation of the organic functional device can thus be reduced considerably.

Furthermore, the reliability obtained through the method according to the present invention is increased since electrode layer segments corresponding to identified defects are electrically isolated, rather than the identified defects exactly pin-pointed and “burned away”.

Through this electrical isolation of segments, the requirements on precision are lowered compared to prior art. Thereby, the method according to the invention can be performed faster and using less sofisticated equipment. Cost can consequently be reduced both in terms of capital expenditure and process time.

The method according to the invention is especially useful in the production of large area organic functional devices, such as OLED-lighting devices, OLED-displays with relatively large pixels (eg. a television display) and organic solar cells etc, since the effect of a short-circuit defect is more serious in these devices than in devices with smaller cells or pixels. As an example, a certain number of defects can generally be tolerated in a high-resolution display with small pixels, since the user will not be able to distinguish the effect of the defects. In a large-area OLED-lighting device (lamp) on the other hand, a few short-circuit defects may lead to total malfunction.

According to one embodiment, the step of identifying a portion may comprise the step of applying a voltage between the electrode layers, this voltage causing current to flow between the electrode layers due to the defect so that heat is generated in the portion containing the defect, and the step of identifying the portion using thermographic techniques.

When a voltage is applied between the electrode layers of an organic functional device, the electric field generally becomes more inhomogenous and greater in a portion of an organic functional device containing a defect than in the surrounding area. Due to the locally more inhomogenous and increased electric field, a larger local current flows between the electrode layers in this portion of the device than in the surrounding portions. The flow of electric current leads to generation of heat, and the portion containing the defect can therefore be identified as a local heat source using thermographic techniques, such as IR-thermography, liquid crystal microscopy, fluorescent microthermal imaging or Schlieren imaging.

According to another embodiment, the step of applying a voltage may be carried out by applying an AC voltage, so that heat is generated periodically, and the step of identifying a portion may be carried out using an IR-detector operating at a frequency related to the frequency of the AC-voltage.

Typically, the operating frequency of the IR-detector is a frequency, which is a multiple of the frequency of the AC-voltage. In other words, if the AC-voltage is f_{R}, the IR-detector frequency is preferably nf_{R}, n=1, 2, . . .

Through this approach, referred to as lock-in IR detection, more information regarding locations of portions containing defects can be obtained.

More specifically, a phase image can be acquired in addition to the amplitude image.

By using the phase image, the effects of heat-dissipation and heat-spreading in the various layers of the device can be filtered out and the portions containing defects thus identified with greater precision.

According to a further embodiment of the present invention, the step of electrically isolating the segment corresponding to a portion of the device containing a defect may be performed using laser irradiation.

Through the use of laser irradiation, neutralization of a potential short-circuit failure can be performed without having to contact any of the electrode layers. The risk of damaging the device during electrical isolation of such segments is thus reduced.

Additionally, test and repair of a finished organic functional device is enabled, whereby the need for special processing environment, such as clean room, inert gas, vacuum or the like is practically eliminated.

The laser irradiation may be continuous or, preferably, pulsed and the laser used may be any laser capable of being tuned to suitable settings for performing the electrical isolation. Such lasers may include various types of gas lasers, such as CO₂-lasers and Excimer lasers, or solid-state lasers, such as Nd-YAG-lasers and fibre lasers.

The laser irradiation may advantageously be applied to the organic functional device from the first transparent electrode layer side.

Thereby, the second electrode layer, which may be transparent or non-transparent, can be patterned individually or together with the first transparent electrode layer through proper selection of laser parameters.

The laser irradiation may be applied through a substrate, on which the first transparent electrode is provided.

The substrate may, for example, be a thin sheet of glass or a suitable plastic, which may be rigid or flexible.

In this way, processing of a sealed product can take place, whereby the need for a special processing environment, such as clean room, inert gas, vacuum or the like is eliminated. This makes the processing cheaper and more reliable.

The electrode layer segment may be selected from the second electrode layer.

Alternatively, two corresponding segments may be selected from the first and second electrode layers respectively and laser settings may be chosen to simultaneously electrically isolate these corresponding segments from the remainders of their respective electrode layers.

By doing this, an even more reliable elimination of short circuit failure is achieved.

Furthermore, a more robust process is provided, since the laser processing window is increased.

These and other aspects of the present invention will now be described in more detail, with reference to the appended drawings showing a currently preferred embodiment of the invention.

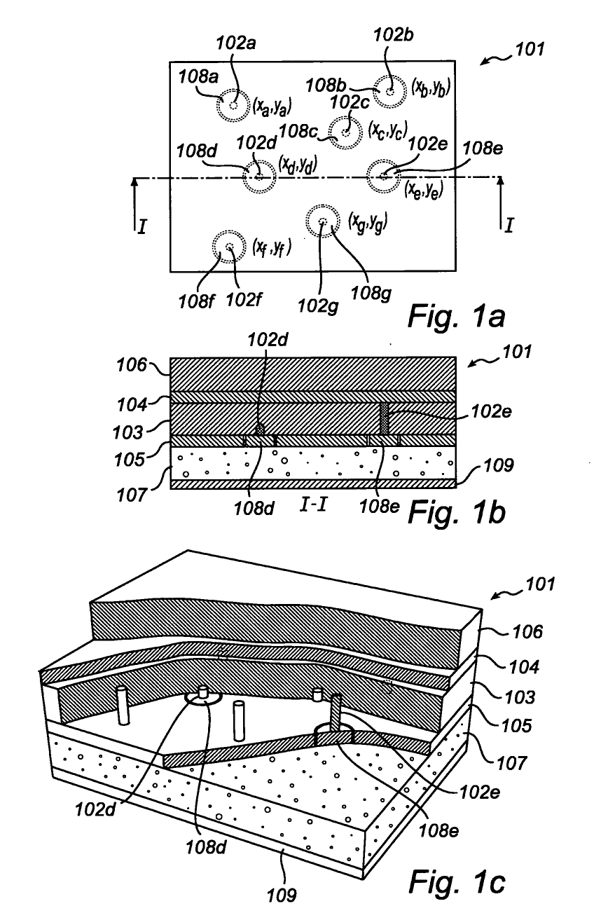

FIG. 1a is a schematic plane view of a first example of an organic functional device, having a number of defect-containing portions and electrically isolated segments.

FIG. 1b is a schematic section view of the organic functional device in FIG. 1a along the line I-I.

FIG. 1c is a schematic perspective view of the organic functional device in FIGS. 1a-b.

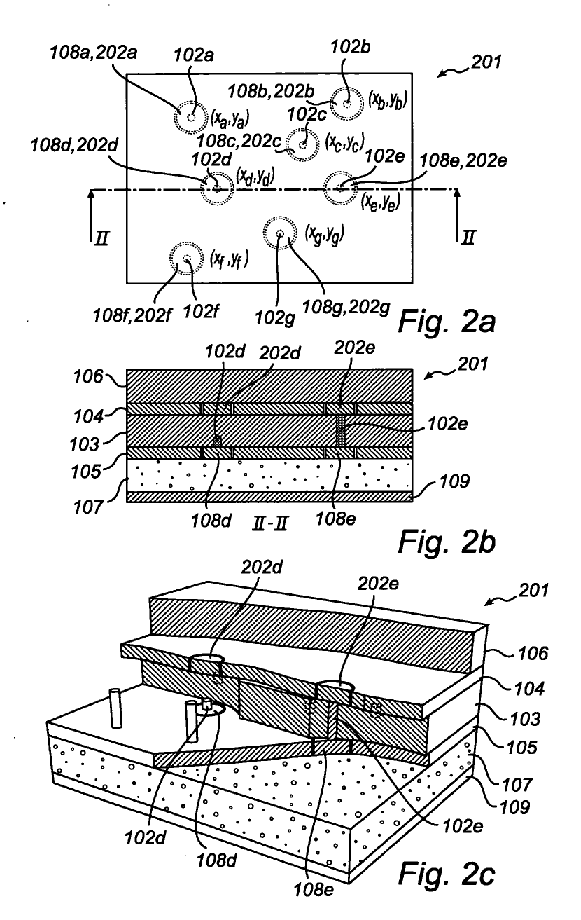

FIG. 2a is a schematic plane view of a second example of an organic functional device, having a number of defect-containing portions and electrically isolated segments.

FIG. 2b is a schematic section view of the organic functional device in FIG. 2a along the line II-II.

FIG. 2c is a schematic perspective view of the organic functional device in FIGS. 2a-b.

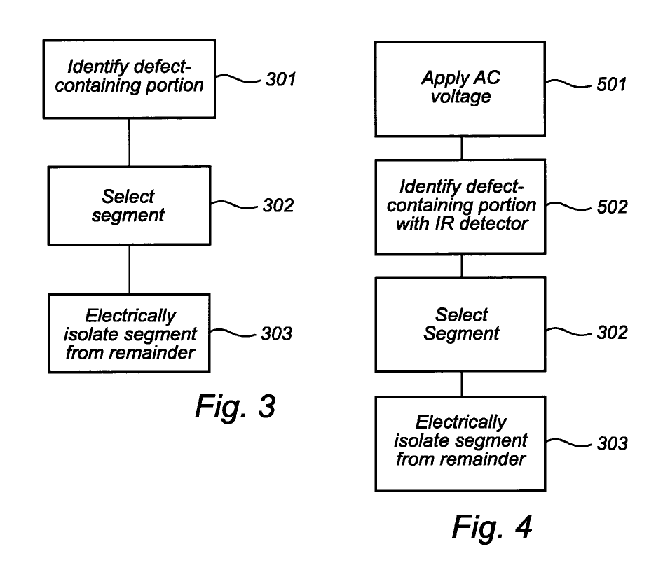

FIG. 3 is a flow chart illustrating a method according to the invention.

FIG. 4 is a flow chart illustrating a preferred embodiment of the method according to the invention.

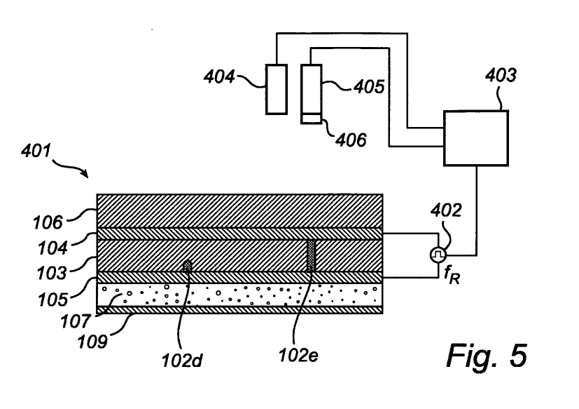

FIG. 5 is a schematic view of an arrangement for carrying out a method according to the preferred embodiment of the method according to the invention.

In the following description, the present invention is described with reference to a light emitting panel. It should be noted that this by no means limits the scope of the invention, which is equally applicable to many organic functional stacks, having a similar structure, used for example as organic solar cells or organic photodiodes.

In FIGS. 1a-c, a first example of an organic light emitting panel 101 is shown. FIG. 1a schematically shows a top view of the light emitting panel 101 having a number of defects with increased risk of short-circuit failure 102a-g at locations (xₐ,yₐ) to (x_{g},y_{g}).

In FIG. 1b, a section view along the line I-I in FIG. 1a is shown, where the layered structure of the organic functional device 101 can be seen and the defects 102d,e at locations (x_{d},y_{d}), (xₑ,yₑ) are also shown. An organic functional layer 103 is sandwiched between a first transparent electrode layer 104 and a second electrode layer 105. Furthermore, segments 108a-g (108d and 108e are visible in FIG. 1b) in the second electrode layer 105 are formed, which correspond to portions of the device containing the defects 102a-g. For support and protection, the organic functional stack constituted by the organic functional layer 103 and the first and second electrode layers 104, 105 is enclosed by a substrate 106 and a protective cover 109. A cavity 107 is formed between this cover 109 and the second electrode layer 105. (Here, a portion of the device 101 is shown. The cavity 107 therefore appears open. It is, however, closed at the boundaries of the device 101.) The substrate 106 is preferably of glass or a suitable plastic material and the cover 109 may be constituted of glass, plastic or a metal. The cavity 107 is filled with a gas, typically Nitrogen gas.

In order to more clearly illustrate a suitable segment 108a-g configuration, the light emitting panel 101 is schematically shown in perspective in FIG. 1c.

In FIGS. 2a-c a second example of an organic functional device 201 is shown. This organic functional device, in the form of an organic light emitting panel 201 differs from the organic light emitting panel 101 shown in FIGS. 1a-c in that the additional segments 202a-g (202d and 202e are visible in FIG. 2b) are indicated in the first transparent electrode layer 104. Apart from this difference, the device 201 in FIGS. 2a-c has the same configuration and exhibits the same defects 102a-g as the device 101 shown in FIGS. 1a-c.

The organic functional layer 103 may generally comprise several organic layers. In case the organic functional device 101, 201 is a polymer light-emitting diode (LED), the organic functional layer 103 essentially comprises a two layer stack of a hole conductor layer and a light emitting polymer layer and may further include several additional layers such as an evaporated organic hole blocking layer on the light emitting polymer.

In case the organic functional device 101, 201 is a small molecule OLED, the organic functional layer 103 is generally formed as a more complex stack including a hole injection layer, a hole transport layer, an electron blocking layer, a light-emitting layer, a hole blocking layer and an electron transporting layer, as well as an electron blocking layer or the like.

The first transparent electrode layer 104 is suitably formed by Indium Tin Oxide (ITO), Indium Zinc Oxide (IZO) or the like or by a thin metal layer formed on a transparent substrate. Such a metal layer should be sufficiently thin to be transparent, i.e. in the range of 5-30 nm.

The second electrode layer 105 is preferably one of Barium (Ba) or Calcium (Ca), Aluminum (Al), Silver (Ag), Zinc Selenide (which is transparent and conductive) or the like or stacks of them and may additionally contain an injection layer, such as Lithium Fluoride (LiF) or the like.

When a voltage is applied between the electrode layers (the anode and the cathode), electrons move from the cathode layer into the OLED device. At the same time holes move from the anode layer into the OLED device.

When the positive and negative charges meet, they recombine and produce photons. The wavelength, and consequently the color, of the photons depends on the properties of the organic material in which the photons are generated. In an OLED device either the cathode layer or the anode layer or both are transparent to the photons generated, allowing the light to emit from the device to the outside world.

In order for the organic light emitting panel 101, 201 to be able to emit light, there thus has to be a sufficient voltage present between the electrode layers 104, 105. In production of organic light emitting panels 101, 201, as well as other types of organic functional devices, such as organic solar cells, defects may be introduced in the form of, for example, pin-holes, dust or other foreign objects. Such defects may, for example, manifest themselves as a short-circuit 102e between the electrode layers 104, 105 or as a particle 102d, which may develop into a short-circuit during operation of the organic light emitting panel 101, 201.

In order to be able to ship the light emitting panel 101, 201 to a customer, it consequently needs to be treated in such a manner that the above mentioned types of defects 102d, 102e, as well as other types of defects, are taken care of.

In FIG. 3 a method according to the invention is illustrated.

In a first step 301, one or several portion(s) of the organic functional device 101, 201 containing defect(s) 102a-g is/are identified. In a consecutive step 302, segment(s) 108d-e, 202d-e of at least one of the first and second electrode layers 104, 105 is/are selected. A selected segment 108d, 202d; 108e, 202e corresponds to a defect-containing portion 102d; 102e of the organic functional device 101; 201.

In the following step 303, the selected segment 108d, 202d; 108e, 202e is electrically isolated from the remainder of the relevant electrode layer 105; 104.

According to a first example of the method according to the invention, segments 108a-g of the second electrode layer are selected 302 so that each of these segments corresponds to at least one previously identified defect-containing portion 102a-g of the light emitting panel 101. Following the selection 302, the segments 108a-g are electrically isolated 303 from the remainder of the second electrode layer. The electrical isolation 303 is preferably effectuated using a laser. The laser is tuned in such a way that the laser irradiation enters the light emitting panel 101 through the substrate 106, continues through the first transparent electrode layer 104 and the organic functional layer 103 without altering the properties of these layers before being absorbed by the second electrode layer 105. Through this laser irradiation, the selected segments 108a-g in the second electrode layer are electrically isolated from the remainder of the second electrode layer 105. One effect of the laser irradiation is that material is ablated at the boundary between the segment 108a-g and the remainder of the second electrode layer 105 so that the electrical connection between the segment and the remainder is broken. Another effect of the heat development during laser treatment is that metal is melted around the laser spot and moved away due to dewetting so that the electrical connection between the segment and the remainder is broken. Generally, the electrical isolation of a segment in the second electrode layer is obtained through either of these effects or a combination thereof.

Examples of suitable laser parameters for achieving the above-described result are:
a) Pulsed Nd-YAG laser, λ=1064 nm, pulse length: approximately 100 ns, pulse frequency 5 kHz, energy distribution: gaussian, average energy density of pulse 1.1 J/cm², number of pulses per position 5.
b) Pulsed Excimer laser, λ=351 nm, pulse length: approximately 20 ns, pulse frequency 100 Hz, energy distribution: top-hat, average energy density of pulse: 0.4 J/cm², number of pulses per position: 16.

Through the above-described electrical isolation 303, a voltage can be maintained between the first and second electrode layers 104, 105 and the light emitting panel can thus function with only minor flaws in the form of small non-emitting spot corresponding to the segments 108a-g.

According to a second example of the method according to the invention, segments 108a-g of the second electrode layer and segments 202a-g of the first transparent electrode layer are selected 302 so that these segments correspond to at least one identified 301 defect-containing portion 102a-g of the light emitting panel 201. Following the selection 302, the segments 108a-g, 202a-g are electrically isolated 303 from the remainder of the second and first electrode layers respectively. The electrical isolation 303 is preferably effectuated using a laser. The laser is tuned in such a way that the laser irradiation enters the light emitting panel 101 through the substrate 106, is partly absorbed by the first transparent electrode layer 104 and passes through the organic functional layer 103 without altering the properties of this layer 103 before being absorbed by the second electrode layer 105. Through this laser irradiation, the selected segments 108a-g of the second electrode layer are electrically isolated from the remainder of the second electrode layer 105 and the selected segments 202a-g of the first transparent electrode layer electrically isolated from the remainder of this layer 104. Due to the local heating of the first electrode layer 104, the conductivity of the first transparent electrode layer is locally decreased to such a degree that the segment 202a-g in the first transparent electrode layer becomes electrically isolated from the remainder of the first electrode layer 104.

Examples of suitable laser parameters for achieving the above-described result are:
a) Pulsed Nd-YAG laser, λ=1064 nm, pulse length: approximately 100 ns, pulse frequency 5 kHz, energy distribution: gaussian, average energy density of pulse 9 J/cm², number of pulses per position 5.
b) a) Pulsed Nd-YAG laser, λ=532 nm, pulse length: approximately 80 ns, pulse frequency 4 kHz, energy distribution: gaussian, average energy density of pulse 0.8 J/cm², number of pulses per position 3.

In the above description it is implied that the step 302 of selection involves selecting all the segments 108a-g; 202a-g prior to performing the step 302 of electrically isolating these segments from the remainder of the respective electrode layers 105;104. Optionally, one segment at a time could be identified 301, selected 302 and then electrically isolated 303 from the remainder of the respective layer.

FIG. 4 shows a block diagram of a preferred embodiment of the method according to the present invention. According to this embodiment, an AC-voltage is, in a first step 501 applied between the electrode layers 104, 105 of the light emitting panel 101, 201. When a voltage between the electrode layers 104, 105 is applied, a leakage current flows between the electrode layers 104, 105 in defect-containing portions 102a-g of the organic light emitting panel 101, 201. Through the current flow, heat is generated at the defect-containing portions 102a-g. As a result of the step 501 of applying an AC-voltage between the electrode layers 104, 105, we thus have a number of pulsating heat sources corresponding to defect-containing portions 102a-g of the organic light emitting panel 101, 201. These defect-containing portions 102a-g are identified 502 using an IR-detector, preferably by lock-in thermography.

Lock-in thermography means that the power dissipated in the object under investigation is periodically amplitude-modulated with frequency f_{R}. The resulting surface temperature modulation is imaged by an IR-detector running with a certain frame rate related (in integer numbers) to the frequency f_{R}, and the generated IR-images are digitally processed according to the lock-in principle. Thus, the effect of lock-in thermography is the same as if each pixel of the IR image were connected with a two-phase lock-in amplifier.

Preferably, images from this IR-detector are grabbed by a computer synchronized with and at a multiple frequency nf_{R} of the frequency f_{R} of the AC-voltage applied between the electrode layers 104, 105. Through this approach, phase information as well as amplitude information can be obtained and the locations (xₐ,yₐ) to (x_{g},y_{g}) of the defect-containing portions 102a-g thereby determined with a higher precision than if only the amplitude information were to be used. When the defect containing portions 102a-g have been identified 502, segments of at least one of the electrode layers 104, 105 are selected 302 so that these segments correspond to the local heat sources 102a-g. In a final step 303, the selected segments are electrically isolated from the remainders of the respective layers using the laser.

In FIG. 5, an arrangement for carrying out the preferred embodiment of the method according to the present invention is schematically shown. Here, an organic functional device in the form of an organic light emitting panel 401 including the same layers 103-107 and defects 102a-g (102d and 102e are visible in FIG. 4) as are also included in FIGS. 1a-c and 2a-c. The first and second electrode layers 104, 105 of this organic light emitting panel 401 are connected to a pulsed voltage source 402 which is controlled by a computer 403 and pulsed at a certain frequency f_{R}. To the computer 403 are also connected a laser 404 and an IR-detector 405. Between the organic light emitting panel 401 and the IR-detector 405, a lens arrangement (having negative or positive magnification depending on the particular situation) is usually placed, here in the form of a macro-lens 406.

The person skilled in the art realises that the present invention by no means is limited to the preferred embodiments described above. On the contrary, many modifications and variations are possible within the scope of the appended claims. For example, the defects 102a-g may be identified using other thermal techniques than the “lock-in thermography” described above. Alternative techniques include liquid crystal microscopy, fluorescent microthermal imaging and Schlieren imaging.

Furthermore, the laser irradiation may be applied from the cover 109 side of the organic functional device 401 if the cover is transparent.

Additionally, the electrically isolated segments 108a-g; 202a-g are here shown as being circular. Of course, any segment shape suitable for the particular application is within the scope of the present invention.

The various organic functional devices described herein are all manufactured in the “traditional” way with a protective cover 109 and a gas-filled cavity 107. The method of the invention is equally applicable for organic functional devices of the thin-film type, in which the protective cover 109 and gas-filled cavity 107 are replaced by a protective layer(s) in the form of, for example, a plastic film or multiple alternating layers of SiₓO_{y} and SiₓN_{y}. This/these protective layer(s) can be added before or, preferably, after the local modification of the electric conductivity according to the invention.

1-10. (canceled)

11. A method, for reducing occurrence of short-circuit failure in an organic functional device (101, 201, 401) comprising a first transparent electrode layer (104), a second electrode layer (105) and an organic functional layer (103) sandwiched between said first and second electrode layers (104; 105), comprising the steps of:
identifying (301) a portion of said organic functional device (101, 201, 401), said portion containing a defect (102a-g) leading to an increased risk of short-circuit failure;
selecting (302) a segment (108a-g) of said second electrode layer (105), said segment corresponding to said portion, and;
electrically isolating (303) said segment (108a-g) from a remainder of said second electrode layer (105), thereby eliminating short-circuit failure resulting from said defect (102a-g), characterized in that said step (301) of identifying a portion comprises the steps of:
applying (501) an AC voltage between said electrode layers (104, 105), said voltage causing current to flow between said electrode layers (104, 105) due to said defect (102a-g) so that heat is generated periodically in said portion, and;
identifying (502) said portion using an IR-detector (405) operating at a frequency (nf_{R}), related to the frequency (f_{R}) of said AC voltage.

12. A method according to claim 11, wherein said step (303) of electrically isolating said segment (108a-g) is performed using laser irradiation.

13. A method according to claim 12, wherein said laser irradiation is applied through said first transparent electrode layer (104).

14. A method according to claim 13, wherein said first transparent electrode layer (104) is provided on a transparent substrate (106) and wherein said laser irradiation is applied through said substrate (106)

15. A method according to claim 11, wherein two corresponding segments (108a-g; 202a-g) are selected (302) from said first and second electrode layers (104; 105) respectively.

16. A method according to claim 15, wherein said corresponding segments (108a-g; 202a-g) are simultaneously electrically isolated from the remainders of their respective electrode layers (105; 104).

17. Use of a method according to claim 11 for manufacturing an organic light-emitting device.

18. Use of a method according to claim 11 for manufacturing an organic solar cell.
